(19) United States
(12) Patent Application Publication
(10) Pub. No.: US 2023/0402290 A1
(43) Pub. Date: Dec. 14, 2023

(54) ATOMIC LAYER ETCHING OF METAL OXIDES USING NOVEL CO-REACTANTS AS HALOGENATING AGENTS FOR SEMICONDUCTOR FABRICATION

(71) Applicants: Merck Patent GmbH, Darmstadt (DE); North Carolina State University, Raleigh, NC (US)

(72) Inventors: Ravindra KANJOLIA, North Andover, MA (US); Jacob WOODRUFF, Lexington, MA (US); Mansour MOINPOUR, San Jose, CA (US); Charles DEZELAH, Helsinki (FI); Wenyi XIE, Elmhurst, NY (US); Holger SAARE, Raleigh, NC (US); Gregory PARSONS, Raleigh, NC (US)

(21) Appl. No.: 18/187,055

(22) Filed: Mar. 21, 2023

Related U.S. Application Data
(60) Provisional application No. 63/366,035, filed on Jun. 8, 2022.

(51) Int. Cl. H01L 21/311; H01L 21/324; H01L 23/532

(52) U.S. Cl. CPC H01L 21/31122; H01L 23/5329; H01L 21/324

(57) ABSTRACT

The disclosed and claimed subject matter relates to thermal ALE processing of metal oxide films using one or more fluorinating agent and one or more chlorinating agent.

### BACKGROUND

### Field

The disclosed and claimed subject matter relates to thermal ALE processing of metal oxide films using one or more fluorinating agent and one or more chlorinating agent.

### Related Art

The miniaturization of features in the semiconductor industry is the main factor behind the continuous performance increase of devices. This trend is expected to continue for at least a few more generations of computer chips. Several technical challenges need to be successfully solved for this trend to continue.

Atomic Layer Deposition (ALD) is one technique finding increased application in the semiconductor industry and it currently is the deposition method allowing the best control on the amount of material deposited. In ALD, a layer of atoms is deposited on all surfaces that are exposed to a precursor in the gas phase—this layer is at most as thick as the thickness of one atomic layer. By sequentially exposing the surfaces to two different precursors, a layer of material with the desired thickness will be deposited. The archetypical example of such a process is the deposition of aluminum oxide (Al₂O₃) from trimethylaluminum (TMA, Al(CH₃)₃) and water (H₂O), where methane (CH₄) is eliminated from the two reacting species. The coating of thin and narrow vias and other high aspect ratio features has been demonstrated numerous times by ALD in the literature.

Atomic Layer Etching (ALE or ALEt) can be viewed as the layer-by-layer subtraction of material when ALD is the layer-by-layer addition of material. In ALE, a layer of atoms is removed from all surfaces of a target material or material type that are exposed to a precursor in the gas phase—this layer is ideally also at most as thick as the thickness of one atomic layer. ALE is performed by sequentially exposing the surfaces to at least two different precursors, a 1^{st} precursor that activates a layer of surface atoms and a 2^{nd} precursor that promotes the sublimation of this activated layer of atoms; sometimes a 3^{rd} precursor or other additional process steps are used to regenerate the surface to the condition where the 1^{st} precursor will be active.

Careful removal of materials is critical to create transistor and memory devices with sub-10 nm features. In this regard, ALE allows precise removal of materials by using sequential and self-limiting half-reaction steps. The key half-reactions during ALE includes an “activation” step, often using a halogenating reagent to modify the surface being etched, followed by a “removal” step, volatilizing the modified surface layer. Plasma based ALE uses plasma activation to promote anisotropic etching of different materials, including Si, Si₃N₄, SiO₂ and Al₂O₃. See, e.g., Carver et al., ECS J. Solid State Sci. Technol., 4, N5005 (2015); Kanarik et al., J Phys. Chem. Lett., 9, 4814 (2018); and Kanarik et al., J. Vac. Sci. Technol. A Vacuum, Surfaces, Film., 33, 020802 (2015). For example, Si ALE proceeds via Cl₂ plasma exposure to form a surface passivating layer of SiClₓ which was then removed upon Ar+ ion bombardment. See Kanarik et al., J. Vac. Sci. Technol. A Vacuum, Surfaces, Film., 33, 020802 (2015). However, even with careful control on the bias power during ion bombardment, repeated exposure of energetic species could lead to change in surface composition and damage of device structure. See Gu et al., IEEE Electron Device Lett., 15, 48 (1994). In thermal based ALE, thermally activated reactions enable isotropic etching of various materials including Al₂O₃, HfO₂, ZrO₂, TiO₂, TiN, SiO₂ and Si₃N₄. See, e.g., Abdulagatov et al., JVSTA, 38, 1 (2020); Lee et al., ECS J. Solid State Sci. Technol., 4, N5013 (2015); Lemaire et al., Chem. Mater., 29, 6653 (2017); Abdulagatov et al., Chem. Mater. 30, acs. chemmater. 8b02745 (2018); Lee et al., J. Vac. Sci. Technol. A, 36, 061504 (2018); and Lee et al., Chem. Mater., 29, 8202 (2017). Thermal ALE processes for compound materials such as metal oxides generally involve surface fluorination with HF, followed by removal of the surface fluoride layer via ligand exchange reaction with Sn(acac)₂, trimethylaluminum (TMA), dimethylaluminum chloride (DMAC), or BCl₃. See, e.g., Lemaire et al., Chem. Mater., 29, 6653 (2017); Lee et al., J. Vac. Sci. Technol. A, 36, 061504 (2018); Lee et al., Chem. Mater., 27, 3648 (2015); George et al., ACS Nano, 10, 4889 (2016); and Lee et al., Chem. Mater., 28, 7657 (2016).

Although Cl₂ and HF are prevalently used in ALE processing, their gaseous state and/or highly corrosive and toxic nature make them difficult to handle safely. In addition, since HF is a highly polar molecule, it tends to stick to the inner walls of the reactor chamber during processing, so long extended purge times are needed to ensure elimination. See, e.g., Xie et al., J. Vac. Sci. Technol. A, 022605 (2020). Therefore, ALE processes that do not rely on HF are highly advantageous for implementation.

In the disclosed and claimed subject matter, thionyl chloride (SOCl₂) and titanium tetrachloride (TiCl₄) are each respectively coupled with WF₆ in a fluorination/ligand-exchange atomic layer etching process. The process is characterized using in-situ ellipsometry, in-vacuo Auger electron spectroscopy (AES), and atomic force microscopy (AFM). The results shown in the Examples indicate that both processes lead to ALE of ZrO₂ and TiO₂. Etching using these processes can be compared to ALE processes using boron trichloride (BCl₃) and WF₆, but with the benefit of avoiding boron residues. See, e.g., Saare et al., J. Appl. Phys. 128, 105302 (2020); Lemaire et al., Chem. Mater., 29, 6653 (2017).

SOCl₂ has been previously shown to continuously etch TiN, which is desirable for higher etching rates but may not yield controlled, isotropic etch in complex 3-dimensional architectures. See Sharma et al., Appl. Surf Sci., 540, 148309 (2021). Additionally, the combination of BCl₃ and WF₆ has been shown to lead to ALE of TiO₂. However, the drawback of using BCl₃ in that process is that it results in a solid B₂O₃ layer which has to be removed by subsequent WF₆ exposure. See Lemaire and Parsons, Chem. Mater., 29, 6653 (2017).

In contrast, in the disclosed and claimed subject matter reaction of SOCl₂ on TiO₂ results only in volatile species, leaving a clean oxide surface. In addition, in the disclosed and claimed subject matter shows that at higher temperatures (>190° C.) the exposure of SOCl₂ leads to vapor etching of TiO₂ by converting the metal oxide to volatile TiCl₄ and SO₂ species, while ZrO₂ is not etched due to the low volatility of ZrCl₄.

### SUMMARY

The disclosed and claimed subject matter relates to processes for the isotropic thermal ALE of metal oxides such as TiO₂, ZrO₂, HfO₂, HfₓZr₁₋ₓO₂ where x is a value between 0 and 1, other materials based on TiO₂, ZrO₂, and/or HfO₂ with engineered impurities or dopants, and combinations thereof. The processes include, consist essentially of or consist of the steps of:
(i) a fluorination that includes exposing the surface of the metal oxide to one or more fluorinating agent to produce a fluorinated surface;
(ii) a first purge;
(iii) a ligand-exchange that includes exposing the fluorinated surface to one or more chlorinating agent to produce a volatile chlorinated species; and
(iv) a second purge.
   In a further aspect of this embodiment, the method consists essentially of steps (i), (ii), (iii) and (iv). In a further aspect of this embodiment, the method consists of steps (i), (ii), (iii) and (iv). The steps in the processes can be cycled as many times as needed to remove a desired thickness of metal oxide. In a further aspect, any of the forgoing embodiments can further include, consist essentially of or consist of a step (v) post-treatment may be added to remove impurities remaining on the surface following a desired number of cycles.

This summary section does not specify every embodiment and/or incrementally novel aspect of the disclosed and claimed subject matter. Instead, this summary only provides a preliminary discussion of different embodiments and corresponding points of novelty over conventional techniques and the known art. For additional details and/or possible perspectives of the disclosed and claimed subject matter and embodiments, the reader is directed to the Detailed Description section and corresponding figures of the disclosure as further discussed below.

The order of discussion of the different steps described herein has been presented for clarity's sake. In general, the steps disclosed herein can be performed in any suitable order. Additionally, although each of the different features, techniques, configurations, etc. disclosed herein may be discussed in different places of this disclosure, it is intended that each of the concepts can be executed independently of each other or in combination with each other as appropriate. Accordingly, the disclosed and claimed subject matter can be embodied and viewed in many different ways.

### BRIEF DESCRIPTION OF THE DRAWINGS

The accompanying drawings, which are included to provide a further understanding of the disclosed subject matter and are incorporated in and constitute a part of this specification, illustrate embodiments of the disclosed subject matter and together with the description serve to explain the principles of the disclosed subject matter. In the drawings:

FIG. 1 illustrates saturation curves of etch rate dependence on WF₆ and co-reactant dose times for TiO₂ (a, b) and for ZrO₂ (c, d); and

FIG. 2 illustrates the influence of substrate temperature on the etch rates during atomic layer etching of (a) TiO₂ and (b) ZrO₂ thin films.

### Definitions

Unless otherwise stated, the following terms used in the specification and claims shall have the following meanings for this application.

For purposes of the disclosed and claimed subject matter, the numbering scheme for the Periodic Table Groups is according to the IUPAC Periodic Table of Elements.

The term “and/or” as used in a phrase such as “A and/or B” herein is intended to include “A and B,” “A or B,” “A” and “B.”

The terms “substituent,” “radical,” “group” and “moiety” may be used interchangeably.

As used herein, the terms “metal-containing complex” (or more simply, “complex”) and “precursor” are used interchangeably and refer to metal-containing molecule or compound which can be used to prepare a metal-containing film by a vapor deposition process such as, for example, ALD or CVD. The metal-containing complex may be deposited on, adsorbed to, decomposed on, delivered to, and/or passed over a substrate or surface thereof, as to form a metal-containing film.

As used herein, the term “metal-containing film” includes not only an elemental metal film as more fully defined below, but also a film which includes a metal along with one or more elements, for example a metal oxide film, metal nitride film, metal silicide film, a metal carbide film and the like. As used herein, the terms “elemental metal film” and “pure metal film” are used interchangeably and refer to a film which consists of, or consists essentially of, pure metal. For example, the elemental metal film may include 100% pure metal or the elemental metal film may include at least about 70%, at least about 80%, at least about 90%, at least about 95%, at least about 96%, at least about 97%, at least about 98%, at least about 99%, at least about 99.9%, or at least about 99.99% pure metal along with one or more impurities. Unless context dictates otherwise, the term “metal film” shall be interpreted to mean an elemental metal film.

As used herein, the term “vapor deposition process” is used to refer to any type of vapor deposition technique, including but not limited to, CVD and ALD. In various embodiments, CVD may take the form of conventional (i.e., continuous flow) CVD, liquid injection CVD, or photo-assisted CVD. CVD may also take the form of a pulsed technique, i.e., pulsed CVD. ALD is used to form a metal-containing film by vaporizing and/or passing at least one metal complex disclosed herein over a substrate surface. For conventional ALD processes see, for example, George S. M., et al. J. Phys. Chem., 1996, 100, 13121-13131. In other embodiments, ALD may take the form of conventional (i.e., pulsed injection) ALD, liquid injection ALD, photo-assisted ALD, plasma-assisted ALD, or plasma-enhanced ALD. The term “vapor deposition process” further includes various vapor deposition techniques described in Chemical Vapour Deposition: Precursors, Processes, and Applications; Jones, A. C.; Hitchman, M. L., Eds., The Royal Society of Chemistry: Cambridge, 2009; Chapter 1, pp. 1-36.

Throughout the description, the terms Atomic Layer Etching or ALE refer to a process including, but is not limited to, the following processes: (i) sequentially introducing each reactant, including the chlorinating agent (e.g., SOCl₂ and/or TiCl₄) and the fluorinating agent (e.g., WF₆), into a reactor such as a single wafer ALD/ALE reactor, semi-batch ALD/ALE reactor, or batch furnace ALD/ALE reactor; (ii) exposing a substrate to each reactant, including the chlorinating agent and the fluorinating agent, by moving or rotating the substrate to different sections of the reactor where each section is separated by inert gas curtain, i.e., spatial ALD/ALE reactor or roll to roll ALD/ALE reactor. It is assumed that an ALE reactor may be similar in design and/or function to an ALD reactor, and vice versa. A typical cycle of an ALE or ALE-like process includes at least four steps as aforementioned.

As used herein, the term “feature” refers to an opening in a substrate which may be defined by one or more sidewalls, a bottom surface, and upper corners. In various aspects, the feature may be a via, a trench, contact, dual damascene, etc.

The term “about” or “approximately,” when used in connection with a measurable numerical variable, refers to the indicated value of the variable and to all values of the variable that are within the experimental error of the indicated value (e.g., within the 95% confidence limit for the mean) or within percentage of the indicated value (e.g., ±10%, ±5%), whichever is greater.

Unless otherwise indicated, “alkyl” refers to a C₁ to C₂₀ hydrocarbon groups which can be linear, branched (e.g., methyl, ethyl, propyl, isopropyl, tert-butyl and the like) or cyclic (e.g., cyclohexyl, cyclopropyl, cyclopentyl and the like). These alkyl moieties may be substituted or unsubstituted as described below. The term “alkyl” refers to such moieties with C₁ to C₂₀ carbons. It is understood that for structural reasons linear alkyls start with C₁, while branched alkyls and linear start with C₃. Moreover, it is further understood that moieties derived from alkyls described below, such as alkyloxy and perfluoroalkyl, have the same carbon number ranges unless otherwise indicated. If the length of the alkyl group is specified as other than described above, the above-described definition of alkyl still stands with respect to it encompassing all types of alkyl moieties as described above and that the structural consideration with regards to minimum number of carbons for a given type of alkyl group still apply.

Halo or halide refers to a halogen, F, Cl, Br or I which is linked by one bond to an organic moiety. In some embodiments, the halogen is F. In other embodiments, the halogen is Cl.

Halogenated alkyl refers to a C₁ to C₂₀ alkyl which is fully or partially halogenated.

Perfluoroalkyl refers to a linear, cyclic or branched saturated alkyl group as defined above in which the hydrogens have all been replaced by fluorine (e.g., trifluoromethyl, perfluoroethyl, perfluoropropyl, perfluorobutyl, perfluoroisopropyl, perfluorocyclohexyl and the like).

The disclosed and claimed precursors are preferably substantially free of organic impurities which are from either starting materials employed during synthesis or by-products generated during synthesis. Examples include, but not limited to, alkanes, alkenes, alkynes, dienes, ethers, esters, acetates, amines, ketones, amides, aromatic compounds. As used herein, the term “free of” organic impurities, means 1000 ppm or less as measured by GC, preferably 500 ppm or less (by weight) as measured by GC, most preferably 100 ppm or less (by weight) as measured by GC or other analytical method for assay. Importantly the precursors preferably have purity of 98 wt. % or higher, more preferably 99 wt. % or higher as measured by GC when used as precursor to deposit the ruthenium-containing films.

The section headings used herein are for organizational purposes and are not to be construed as limiting the subject matter described. All documents, or portions of documents, cited in this application, including, but not limited to, patents, patent applications, articles, books, and treatises, are hereby expressly incorporated herein by reference in their entirety for any purpose. In the event that any of the incorporated literature and similar materials defines a term in a manner that contradicts the definition of that term in this application, this application controls.

### DETAILED DESCRIPTION

It is to be understood that both the foregoing general description and the following detailed description are illustrative and explanatory, and are not restrictive of the subject matter, as claimed. The objects, features, advantages and ideas of the disclosed subject matter will be apparent to those skilled in the art from the description provided in the specification, and the disclosed subject matter will be readily practicable by those skilled in the art on the basis of the description appearing herein. The description of any “preferred embodiments” and/or the examples which show preferred modes for practicing the disclosed subject matter are included for the purpose of explanation and are not intended to limit the scope of the claims.

It will also be apparent to those skilled in the art that various modifications may be made in how the disclosed subject matter is practiced based on described aspects in the specification without departing from the spirit and scope of the disclosed subject matter disclosed herein.

In one embodiment, the disclosed and claimed subject matter relates to processes for the isotropic thermal ALE of metal oxides, including TiO₂, ZrO₂, HfO₂, HfₓZr₁₋ₓO₂ where x is a value between 0 and 1, other materials based on TiO₂, ZrO₂, and/or HfO₂ with engineered impurities or dopants, and combinations thereof. The processes include, consist essentially of or consist of the steps of:
(i) a fluorination that includes exposing the surface of the metal oxide to one or more fluorinating agent to produce a fluorinated surface;
(ii) a first purge;
(iii) a ligand-exchange that includes exposing the fluorinated surface to one or more chlorinating agent to produce a volatile chlorinated species; and
(iv) a second purge.
   In a further aspect of this embodiment, the method consists essentially of steps (i), (ii), (iii) and (iv). In a further aspect of this embodiment, the method consists of steps (i), (ii), (iii) and (iv). The steps in the processes can be cycled as many times as needed to remove a desired thickness of metal oxide. In a further aspect, any of the forgoing embodiments can further include, consist essentially of or consist of a step (v) post-treatment may be added to remove impurities remaining on the surface following a desired number of cycles.

Specific aspects of the disclosed and claimed subject matter are exemplified below.

Metal Oxides

As discussed above, the disclosed and claimed subject matter relates to thermal ALE processing of metal oxides. Suitable metal oxides include, but are not limited to, TiO₂, ZrO₂, HfO₂, HfₓZr₁₋ₓO₂ where x is a value between 0 and 1, other materials based on TiO₂, ZrO₂, and/or HfO₂ with engineered impurities or dopants, and combinations thereof

In one embodiment, the metal oxide includes TiO₂.

In one embodiment, the metal oxide includes ZrO₂.

Step (i) Fluorination

As discussed above, in the disclosed and claimed processes, the step (i) fluorination includes exposing the surface of the metal oxide to one or more fluorinating agent to produce a fluorinated surface.

Fluorinating Agents

The one or more fluorinating agent includes one or more metal fluoride. In one aspect of this embodiment, the one or more metal fluoride is WF₆.

Step (iii) Ligand-Exchange

As discussed above, in the disclosed and claimed processes, the step (iii) ligand-exchange includes exposing the fluorinated surface to one or more chlorinating agent to produce a volatile chlorinated species.

Chlorinating Agent

The one or more chlorinating agent includes one or more chlorine source. In one aspect of this embodiment, the one or more chlorinating agent is one or more of thionyl chloride (SOCl₂), titanium tetrachloride (TiCl₄), and combinations thereof. In one aspect of this embodiment, the one or more chlorinating agent includes SOCl₂. In one aspect of this embodiment, the one or more chlorinating agent includes TiCl₄. In one aspect of this embodiment, the one or more chlorinating agent includes more than one of SOCl₂ and TiCl₄.

Temperatures

As discussed above, step (i) of the disclosed and claimed subject matter is performed at an elevated temperature. In one embodiment step (i) is performed at temperature between about 140° C. and about 350° C. In one embodiment step (i) is performed at temperature between about 140° C. and about 325° C. In one embodiment step (i) is performed at temperature between about 140° C. and about 300° C. In one embodiment step (i) is performed at temperature between about 140° C. and about 275° C. In one embodiment step (i) is performed at temperature between about 150° C. and about 300° C. In one embodiment step (i) is performed at temperature between about 150° C. and about 275° C. In one embodiment step (i) is performed at temperature between about 175° C. and about 275° C. In one embodiment step (i) is performed at temperature between about 200° C. and about 275° C. In one embodiment step (i) is performed at temperature between about 225° C. and about 275° C. In one embodiment step (i) is performed at temperature between about 200° C. and about 250° C. In one embodiment step (i) is performed at temperature of about 140° C. In one embodiment step (i) is performed at temperature of about 150° C. In one embodiment step (i) is performed at temperature of about 160° C. In one embodiment step (i) is performed at temperature of about 170° C. In one embodiment step (i) is performed at temperature of about 180° C. In one embodiment step (i) is performed at temperature of about 190° C. In one embodiment step (i) is performed at temperature of about 200° C. In one embodiment step (i) is performed at temperature of about 210° C. In one embodiment step (i) is performed at temperature of about 220° C. In one embodiment step (i) is performed at temperature of about 230° C. In one embodiment step (i) is performed at temperature of about 240° C. In one embodiment step (i) is performed at temperature of about 250° C. In one embodiment step (i) is performed at temperature of about 260° C. In one embodiment step (i) is performed at temperature of about 270° C. In one embodiment step (i) is performed at temperature of about 280° C. In one embodiment step (i) is performed at temperature of about 290° C. In one embodiment step (i) is performed at temperature of about 300° C. In one embodiment step (i) is performed at temperature of about 310° C. In one embodiment step (i) is performed at temperature of about 320° C. In one embodiment step (i) is performed at temperature of about 325° C. In one preferred embodiment, step (i) is performed at temperature of about 350° C.

As discussed above, step (iii) of the disclosed and claimed subject matter is performed at an elevated temperature. In one embodiment step (iii) is performed at temperature between about 140° C. and about 350° C. In one embodiment step (iii) is performed at temperature between about 140° C. and about 325° C. In one embodiment step (iii) is performed at temperature between about 140° C. and about 300° C. In one embodiment step (iii) is performed at temperature between about 140° C. and about 275° C. In one embodiment step (iii) is performed at temperature between about 150° C. and about 300° C. In one embodiment step (iii) is performed at temperature between about 150° C. and about 275° C. In one embodiment step (iii) is performed at temperature between about 175° C. and about 275° C. In one embodiment step (iii) is performed at temperature between about 200° C. and about 275° C. In one embodiment step (iii) is performed at temperature between about 225° C. and about 275° C. In one embodiment step (iii) is performed at temperature between about 200° C. and about 250° C. In one embodiment step (iii) is performed at temperature of about 140° C. In one embodiment step (iii) is performed at temperature of about 150° C. In one embodiment step (iii) is performed at temperature of about 160° C. In one embodiment step (iii) is performed at temperature of about 170° C. In one embodiment step (iii) is performed at temperature of about 180° C. In one embodiment step (iii) is performed at temperature of about 190° C. In one embodiment step (iii) is performed at temperature of about 200° C. In one embodiment step (iii) is performed at temperature of about 210° C. In one embodiment step (iii) is performed at temperature of about 220° C. In one embodiment step (iii) is performed at temperature of about 230° C. In one embodiment step (iii) is performed at temperature of about 240° C. In one embodiment step (iii) is performed at temperature of about 250° C. In one embodiment step (iii) is performed at temperature of about 260° C. In one embodiment step (iii) is performed at temperature of about 270° C. In one embodiment step (iii) is performed at temperature of about 280° C. In one embodiment step (iii) is performed at temperature of about 290° C. In one embodiment step (iii) is performed at temperature of about 300° C. In one embodiment step (iii) is performed at temperature of about 310° C. In one embodiment step (iii) is performed at temperature of about 320° C. In one embodiment step (iii) is performed at temperature of about 325° C. In one preferred embodiment, step (iii) is performed at temperature of about 350° C.

In one embodiment, step (i) and step (iii) are each performed at about the same temperature. In a further aspect of this embodiment, step (i) and step (iii) are each performed at the same temperature. In another embodiment, step (i) and step (iii) are each performed at a different temperature.

Cycles

As those skilled in the art will appreciate, steps (i) and (iii) of the disclosed and claimed subject matter are conducted in cycles in order to achieve a desired degree of etch. A single cycle of the disclosed and claimed method includes:

(step (i))ₙ+(step (iii))ₘ

where n and m each independently=1-20 and represent the number of times (i.e., the number of iterations) that step (i) and step (iii) are each performed within a single cycle. As those skilled in the art will understand, the disclosed and claimed process will include a purge step (ii) when proceeding from step (i) to step (iii) as well as an additional purge step (iv) before beginning a new cycle (i.e., proceeding from step (iii) to step (i)). However, purge steps do not have to be performed between iterations of a single step (e.g., between multiple iterations of step (i) or between multiple iterations of step (iii)). Thus, a single cycle is to be understood as beginning when the first iteration of step (i) is performed and ending when the last purge step (iv) is performed before another iteration of step (i) is performed again regardless of the number of purging steps conducted during the process.

In one embodiment, n and m are the same.

In one embodiment, n and m are different.

In one embodiment, n is the same as m. In one embodiment, n is different from m.

In one embodiment n=1. In one embodiment n=2. In one embodiment n=3. In one embodiment n=4. In one embodiment n=5. In one embodiment n=6. In one embodiment n=7. In one embodiment n=8. In one embodiment n=9. In one embodiment n=10. In one embodiment n=11. In one embodiment n=12. In one embodiment n=13. In one embodiment n=14. In one embodiment n=15. In one embodiment n=16. In one embodiment n=17. In one embodiment n =18. In one embodiment n=19. In one embodiment n=20.

In one embodiment m=1. In one embodiment m=2. In one embodiment m=3. In one embodiment m=4. In one embodiment m=5. In one embodiment m=6. In one embodiment m=7. In one embodiment m=8. In one embodiment m=9. In one embodiment m=10. In one embodiment m=11. In one embodiment m=12. In one embodiment m=13. In one embodiment m=14. In one embodiment m=15. In one embodiment m=16. In one embodiment m=17. In one embodiment m=18. In one embodiment m=19. In one embodiment m=20.

In one embodiment n=1 and m=1. In one embodiment n=2 and m=2. In one embodiment n=3 and m=3. In one embodiment n=4 and m=4. In one embodiment n=5 and m=5. In one embodiment n=6 and m=6. In one embodiment n=7 and m=7. In one embodiment n=8 and m=8. In one embodiment n=9 and m=9. In one embodiment n=10 and m=10. In one embodiment n=11 and m=11. In one embodiment n=12 and m=12. In one embodiment n=13 and m=13. In one embodiment n=14 and m=14. In one embodiment n=15 and m=15. In one embodiment n=16 and m=16. In one embodiment n=17 and m=17. In one embodiment n=18 and m=18. In one embodiment n=19 and m=19. In one embodiment n=20 and m=20.

In one embodiment, each iteration of step (i) alternates with an iteration of step (iii) within each cycle (i.e., alternating between each iteration of step (i) with an iteration of step (iii)). In another embodiment, all iterations of step (i) are begun and completed before the iterations of step (iii) are begun and completed within in each cycle.

### Number of Cycles

The disclosed and claimed process can include any number of desired cycles. In one embodiment, the number of cycles is from about 5 to about 5000. In one embodiment, the number of cycles is from about 10 to about 1000. In one embodiment, the number of cycles is from about 50 to about 2500. In one embodiment, the number of cycles is from about 50 to about 1500. In one embodiment, the number of cycles is from about 50 to about 1000. In one embodiment, the number of cycles is from about 50 to about 750. In one embodiment, the number of cycles is from about 50 to about 500. In one embodiment, the number of cycles is from about 50 to about 300. In one embodiment, the number of cycles is from about 50 to about 200. In one embodiment, the number of cycles is from about 10 to about 50. In one embodiment, the number of cycles is from about 150 to about 4000. In one embodiment, the number of cycles is from about 200 to about 3000. In one embodiment, the number of cycles is from about 250 to about 2500. In one embodiment, the number of cycles is from about 350 to about 2000. In one embodiment, the number of cycles is from about 450 to about 1700. In one embodiment, the number of cycles is from about 500 to about 1500. In one embodiment, the number of cycles is from about 750 to about 1250. In one embodiment, the number of cycles is from about 250 to about 1000. In one embodiment, the number of cycles is from about 500 to about 1000. In one embodiment, the number of cycles is from about 750 to about 1000.

In one embodiment, the number of cycles is about 5. In one embodiment, the number of cycles is about 10. In one embodiment, the number of cycles is about 15. In one embodiment, the number of cycles is about 20. In one embodiment, the number of cycles is about 25. In one embodiment, the number of cycles is about 30. In one embodiment, the number of cycles is about 40. In one embodiment, the number of cycles is about 50. In one embodiment, the number of cycles is about 100. In one embodiment, the number of cycles is about 125. In one embodiment, the number of cycles is about 150. In one embodiment, the number of cycles is about 175. In one embodiment, the number of cycles is about 200. In one embodiment, the number of cycles is about 250. In one embodiment, the number of cycles is about 300. In one embodiment, the number of cycles is about 350. In one embodiment, the number of cycles is about 400. In one embodiment, the number of cycles is about 450. In one embodiment, the number of cycles is about 500. In one embodiment, the number of cycles is about 750. In one embodiment, the number of cycles is about 1000. In one embodiment, the number of cycles is about 1250. In one embodiment, the number of cycles is about 1500. In one embodiment, the number of cycles is about 1750. In one embodiment, the number of cycles is about 2000. In one embodiment, the number of cycles is about 2250. In one embodiment, the number of cycles is about 2500. In one embodiment, the number of cycles is about 2750. In one embodiment, the number of cycles is about 3000. In one embodiment, the number of cycles is about 3250. In one embodiment, the number of cycles is about 3500. In one embodiment, the number of cycles is about 4000. In one embodiment, the number of cycles is about 4500. In one embodiment, the number of cycles is about 5000.

Time

In one embodiment of the disclosed and claimed subject matter, each iteration of step (i) can take between about 0.05 seconds and about 60 seconds. In one embodiment of the disclosed and claimed subject matter, each iteration of step (i) can take between about 20 seconds and about 60 seconds. In one embodiment of the disclosed and claimed subject matter, each iteration of step (i) can take between about 5 seconds and about 20 seconds. In one embodiment of the disclosed and claimed subject matter, each iteration of step (i) can take between about 1 second and about 5 seconds. In one embodiment, each iteration of step (i) can take between about 0.05 seconds and about 0.9 second. In one embodiment, each iteration of step (i) can take between about 0.3 seconds and about 0.8 second. In one embodiment, each iteration of step (i) can take between about 0.4 seconds and about 0.7 second. In one embodiment, each iteration of step (i) takes about 0.05 seconds. In one embodiment, each iteration of step (i) takes about 0.1 seconds. In one embodiment, each iteration of step (i) takes about seconds. In one embodiment, each iteration of step (i) takes about 0.2 seconds. In one embodiment, each iteration of step (i) takes about 0.3 seconds. In one embodiment, each iteration of step (i) takes about 0.4 seconds. In one embodiment, each iteration of step (i) takes about 0.5 seconds. In one embodiment, each iteration of step (i) takes about 0.6 seconds. In one embodiment, each iteration of step (i) takes about 0.7 seconds. In one embodiment, each iteration of step (i) takes about 0.8 seconds. In one embodiment, each iteration of step (i) takes about 0.9 seconds. In one embodiment, each iteration of step (i) takes about 1 second. In one embodiment, each iteration of step (i) takes about 2 seconds. In one embodiment, each iteration of step (i) takes about 3 seconds. In one embodiment, each iteration of step (i) takes about 4 seconds. In one embodiment, each iteration of step (i) takes about 5 seconds. In one embodiment, each iteration of step (i) takes about 7 seconds. In one embodiment, each iteration of step (i) takes about 10 seconds. In one embodiment, each iteration of step (i) takes about 15 seconds. In one embodiment, each iteration of step (i) takes about 20 seconds. In one embodiment, each iteration of step (i) takes about 30 seconds. In one embodiment, each iteration of step (i) takes about 40 seconds. In one embodiment, each iteration of step (i) takes about seconds. In one embodiment, each iteration of step (i) takes about 60 seconds.

In one embodiment of the disclosed and claimed subject matter, each iteration of step (iii) can take between about 0.05 seconds and about 60 seconds. In one embodiment of the disclosed and claimed subject matter, each iteration of step (iii) can take between about 20 seconds and about seconds. In one embodiment of the disclosed and claimed subject matter, each iteration of step (iii) can take between about 5 seconds and about 20 seconds. In one embodiment of the disclosed and claimed subject matter, each iteration of step (iii) can take between about 1 second and about 5 seconds. In one embodiment, each iteration of step (iii) can take between about 0.2 seconds and about second. In one embodiment, each iteration of step (iii) can take between about 0.3 seconds and about 0.8 second. In one embodiment, each iteration of step (iii) can take between about 0.4 seconds and about 0.7 second. In one embodiment, each iteration of step (iii) takes about 0.05 seconds. In one embodiment, each iteration of step (iii) takes about 0.1 seconds. In one embodiment, each iteration of step (iii) takes about 0.15 seconds. In one embodiment, each iteration of step (iii) takes about 0.2 seconds. In one embodiment, each iteration of step (iii) takes about 0.3 seconds. In one embodiment, each iteration of step (iii) takes about 0.4 seconds. In one embodiment, each iteration of step (iii) takes about 0.5 seconds. In one embodiment, each iteration of step (iii) takes about 0.6 seconds. In one embodiment, each iteration of step (iii) takes about 0.7 seconds. In one embodiment, each iteration of step (iii) takes about 0.8 seconds. In one embodiment, each iteration of step (iii) takes about 0.9 seconds. In one embodiment, each iteration of step (iii) takes about 1 second. In one embodiment, each iteration of step (iii) takes about 2 seconds. In one embodiment, each iteration of step (iii) takes about 3 seconds. In one embodiment, each iteration of step (iii) takes about 4 seconds. In one embodiment, each iteration of step (iii) takes about 5 seconds. In one embodiment, each iteration of step (iii) takes about 7 seconds. In one embodiment, each iteration of step (iii) takes about 10 seconds. In one embodiment, each iteration of step (iii) takes about 15 seconds. In one embodiment, each iteration of step (iii) takes about 20 seconds. In one embodiment, each iteration of step (iii) takes about 30 seconds. In one embodiment, each iteration of step (iii) takes about 40 seconds. In one embodiment, each iteration of step (iii) takes about 50 seconds. In one embodiment, each iteration of step (iii) takes about 60 seconds.

In one embodiment, each iteration of step (i) in a cycle takes about the same amount of time. In one embodiment, one or more iteration of step (i) in a cycle takes a different amount of time than another iteration of step (i) in the cycle.

In one embodiment, each iteration of step (iii) in a cycle takes about the same amount of time. In one embodiment, one or more iteration of step (iii) in a cycle takes a different amount of time than another iteration of step (iii) in the cycle.

In one embodiment, each iteration of step (i) in a cycle takes about the same amount of time as each iteration of step (iii) in the cycle. In one embodiment, each iteration of step (i) in a cycle takes a different amount of time as each iteration of step (iii) in the cycle.

Exemplary Description of a Cycle

In one embodiment, for example, one cycle would include six (6) 0.15 second step (i) doses of WF₆ followed by six (6) 0.25 second step (iii) doses of SOCl₂. This cycle could be described as “6(0.15 s WF₆)/6(0.25 s SOCl₂).”

Chamber (Reactor) Pressures

Fluorinating and Chlorinating Agent Pressures

In one embodiment, the fluorinating agent and/or chlorinating agent is delivered into the chamber from one port while an inert gas is delivered into the chamber though the same port. In one embodiment, the fluorinating agent and/or chlorinating agent is delivered into the chamber from one port while an inert gas is delivered into the chamber from another port. In one embodiment, the fluorinating agent and/or chlorinating agent is delivered by flowing inert gas through the halogenating agent, forming a mixed vapor. In one embodiment, the fluorinating agent and/or chlorinating agent is delivered neat. In one embodiment, the total pressure in the chamber during the fluorinating agent and/or chlorinating agent delivery is from about 0.1 Torr to about 1.0 Torr. In one embodiment, the total pressure in the chamber during the fluorinating agent and/or chlorinating agent delivery is from about 0.5 Torr to about 5.0 Torr. In one embodiment, the total pressure in the chamber during the fluorinating agent and/or chlorinating agent delivery is from about 0.5 Torr to about 2.0 Torr. In one embodiment, the total pressure in the chamber during the fluorinating agent and/or chlorinating agent delivery is from about 0.5 Torr to about 1.0 Torr. In one embodiment, the total pressure in the chamber during the fluorinating agent and/or chlorinating agent delivery is from about 0.5 Torr to about 0.75 Torr. In one embodiment, the total pressure in the chamber during the fluorinating agent and/or chlorinating agent delivery is from about 1.0 Torr to about 5.0 Torr. In one embodiment, the total pressure in the chamber during the fluorinating agent and/or chlorinating agent delivery is from about 1.0 Torr to about 10.0 Torr. In one embodiment, the total pressure in the chamber during the fluorinating agent and/or chlorinating agent delivery is from about 2.0 Torr to about 10.0 Torr. In one embodiment, the total pressure in the chamber during the fluorinating agent and/or chlorinating agent delivery is from about 10.0 Torr to about 25.0 Torr. In one embodiment, the total pressure in the chamber during the fluorinating agent and/or chlorinating agent delivery is from about 10.0 Torr to about 50.0 Torr. In one embodiment, the total pressure in the chamber during the fluorinating agent and/or chlorinating agent delivery is from about 25.0 Torr to about 50.0 Torr. In one embodiment, the total pressure in the chamber during the fluorinating agent and/or chlorinating agent delivery is from about 50.0 Torr to about 75.0 Torr. In one embodiment, the total pressure in the chamber during the fluorinating agent and/or chlorinating agent delivery is from about 75.0 Torr to about 100.0 Torr. In one embodiment, the total pressure in the chamber during the fluorinating agent and/or chlorinating agent delivery is from about 1.0 Torr to about 100.0 Torr. In one embodiment, the total pressure in the chamber during the fluorinating agent and/or chlorinating agent delivery is from about 10.0 Torr to about 100.0 Torr.

In one embodiment the fluorinating agent and chlorinating agent are delivered at the same pressure. In one embodiment the fluorinating agent and chlorinating agent are delivered at the substantially same pressure. In one embodiment, the fluorinating agent and/or chlorinating agent are delivered at different pressures.

Delivery Method

In one embodiment, the fluorinating agent and/or chlorinating agent is delivered by vapor-draw. In one embodiment, the fluorinating agent and/or chlorinating agent is delivered by flowing an inert gas through a container of the fluorinating agent and/or chlorinating agent. In one embodiment, the fluorinating agent and/or chlorinating agent is delivered as a gas.

Steps (ii) and (iv) Purging

Purge Gas

When performing step (ii) and/or step (iv), any suitable inert purge gas can be used. In one embodiment, the purge gas includes argon. In one embodiment, the purge gas includes nitrogen.

In one embodiment, the purge gas in step (ii) and step (iv) is the same. In one embodiment, the purge gas in step (ii) and step (iv) is different.

Time

In one embodiment, the step (ii) and/or step (iv) purge time is from about 0.25 seconds to about 10 seconds. In one embodiment, the step (ii) and/or step (iv) purge time exposure is from about 1 second to about 7 seconds. In one embodiment, the step (ii) and/or step (iv) purge time exposure is from about 7 seconds to about 10 seconds. In one embodiment, the step (ii) and/or step (iv) purge time exposure is from about 10 seconds to about 20 seconds. In one embodiment, the step (ii) and/or step (iv) purge time exposure is from about 20 seconds to about 30 seconds. In one embodiment, the step (ii) and/or step (iv) purge time exposure is from about 30 seconds to about 60 seconds. In one embodiment, the step (ii) and/or step (iv) purge time exposure is about 0.25 seconds. In one embodiment, the step (ii) and/or step (iv) purge time exposure is about 0.5 seconds. In one embodiment, the step (ii) and/or step (iv) purge time exposure is about 1 second. In one embodiment, the step (ii) and/or step (iv) purge time exposure is about 2 seconds. In one embodiment, the step (ii) and/or step (iv) purge time exposure is about 3 seconds. In one embodiment, the step (ii) and/or step (iv) purge time exposure is about 4 seconds. In one embodiment, the step (ii) and/or step (iv) purge time exposure is about 5 seconds. In one embodiment, the step (ii) and/or step (iv) purge time exposure is about 6 seconds. In one embodiment, the step (ii) and/or step (iv) purge time exposure is about 7 seconds. In one embodiment, the step (ii) and/or step (iv) purge time exposure is about 8 seconds. In one embodiment, the step (ii) and/or step (iv) purge time exposure is about 9 seconds. In one embodiment, the step (ii) and/or step (iv) purge time exposure is about 10 seconds. In one embodiment, the step (ii) and/or step (iv) purge time exposure is about 12 seconds. In one embodiment, the step (ii) and/or step (iv) purge time exposure is about 15 seconds. In one embodiment, the step (ii) and/or step (iv) purge time exposure is about 17 seconds. In one embodiment, the step (ii) and/or step (iv) purge time exposure is about 20 seconds. In one embodiment, the step (ii) and/or step (iv) purge time exposure is about 25 seconds. In one embodiment, the step (ii) and/or step (iv) purge time exposure is about 30 seconds. In one embodiment, the step (ii) and/or step (iv) purge time exposure is about 40 seconds. In one embodiment, the step (ii) and/or step (iv) purge time exposure is about 50 seconds. In one embodiment, the step (ii) and/or step (iv) purge time exposure is about 60 seconds.

In one embodiment, the purge gas in step (ii) and step (iv) is flowed for the same amount of time. In one embodiment, the purge gas in step (ii) and step (iv) is flowed for a different amount of time.

Flow Rate

When performing step (ii) and/or step (iv), the purge gas is flowed at between about 1 sccm to about 2000 sccm. In one embodiment, the step (ii) and/or step (iv) purge gas is flowed at between about 3 sccm to about 8 sccm. In one embodiment, the step (ii) and/or step (iv) purge gas is flowed at between about 50 sccm to about 500 sccm. In one embodiment, the step (ii) and/or step (iv) purge gas is flowed at between about 500 sccm to about 2000 sccm. In one embodiment, the step (ii) and/or step (iv) purge gas is flowed at about 1 sccm. In one embodiment, the step (ii) and/or step (iv) purge gas is flowed at about 2 sccm. In one embodiment, the step (ii) and/or step (iv) purge gas is flowed at about 3 sccm. In one embodiment, the step (ii) and/or step (iv) purge gas is flowed at about 4 sccm. In one embodiment, the step (ii) and/or step (iv) purge gas is flowed at about 5 sccm. In one embodiment, the step (ii) and/or step (iv) purge gas is flowed at about 6 sccm. In one embodiment, the step (ii) and/or step (iv) purge gas is flowed at about 7 sccm. In one embodiment, the step (ii) and/or step (iv) purge gas is flowed at about 8 sccm. In one embodiment, the step (ii) and/or step (iv) purge gas is flowed at about 9 sccm. In one embodiment, the step (ii) and/or step (iv) purge gas is flowed at about 10 sccm. In one embodiment, the step (ii) and/or step (iv) purge gas is flowed at about 9 sccm. In one embodiment, the step (ii) and/or step (iv) purge gas is flowed at about 10 sccm. In one embodiment, the step (ii) and/or step (iv) purge gas is flowed at about 50 sccm. In one embodiment, the step (ii) and/or step (iv) purge gas is flowed at about 100 sccm. In one embodiment, the step (ii) and/or step (iv) purge gas is flowed at about 200 sccm. In one embodiment, the step (ii) and/or step (iv) purge gas is flowed at about 300 sccm. In one embodiment, the step (ii) and/or step (iv) purge gas is flowed at about 500 sccm. In one embodiment, the step (ii) and/or step (iv) purge gas is flowed at about 750 sccm. In one embodiment, the step (ii) and/or step (iv) purge gas is flowed at about 1000 sccm. In one embodiment, the step (ii) and/or step (iv) purge gas is flowed at about 1250 sccm. In one embodiment, the step (ii) and/or step (iv) purge gas is flowed at about 1500 sccm. In one embodiment, the step (ii) and/or step (iv) purge gas is flowed at about 1750 sccm. In one embodiment, the step (ii) and/or step (iv) purge gas is flowed at about 2000 sccm.

In one embodiment, the purge gas in step (ii) and step (iv) is flowed at the same rate. In one embodiment, the purge gas in step (ii) and step (iv) is flowed at a different rate.

Films

The disclosed and claimed subject matter further includes films modified or etched by the methods described herein.

In one embodiment, the films modified or etched by the methods described herein have trenches, vias or other topographical features with an aspect ratio of about 0 to about 60. In a further aspect of this embodiment, the aspect ratio is about 0 to about 0.5. In a further aspect of this embodiment, the aspect ratio is about 0.5 to about 1. In a further aspect of this embodiment, the aspect ratio is about 1 to about 50. In a further aspect of this embodiment, the aspect ratio is about 1 to about 40. In a further aspect of this embodiment, the aspect ratio is about 1 to about 30. In a further aspect of this embodiment, the aspect ratio is about 1 to about 20. In a further aspect of this embodiment, the aspect ratio is about 1 to about 10. In a further aspect of this embodiment, the aspect ratio is about 0.1. In a further aspect of this embodiment, the aspect ratio is about 0.2. In a further aspect of this embodiment, the aspect ratio is about 0.3. In a further aspect of this embodiment, the aspect ratio is about 0.4. In a further aspect of this embodiment, the aspect ratio is about 0.5. In a further aspect of this embodiment, the aspect ratio is about 0.6. In a further aspect of this embodiment, the aspect ratio is about 0.8. In a further aspect of this embodiment, the aspect ratio is about 1. In a further aspect of this embodiment, the aspect ratio is greater than about 1. In a further aspect of this embodiment, the aspect ratio is greater than about 2. In a further aspect of this embodiment, the aspect ratio is greater than about 5. In a further aspect of this embodiment, the aspect ratio is greater than about 10. In a further aspect of this embodiment, the aspect ratio is greater than about 15. In a further aspect of this embodiment, the aspect ratio is greater than about 20. In a further aspect of this embodiment, the aspect ratio is greater than about 30. In a further aspect of this embodiment, the aspect ratio is greater than about 40. In a further aspect of this embodiment, the aspect ratio is greater than about 50.

In a further aspect of the forgoing embodiments and aspects thereof, the film includes titanium and zirconium. In a further aspect of the forgoing embodiments and aspects thereof, the film includes titanium or zirconium. In a further aspect of the forgoing embodiments and aspects thereof, the film includes titanium. In a further aspect of the forgoing embodiments and aspects thereof, the film includes zirconium. In a further aspect of the forgoing embodiments and aspects thereof, the film includes TiO₂. In a further aspect of the forgoing embodiments and aspects thereof, the film includes ZrO₂.

In a further aspect of the forgoing embodiments and aspects thereof, the film includes zirconium or hafnium. In a further aspect of the forgoing embodiments and aspects thereof, the film includes zirconium and hafnium. In a further aspect of the forgoing embodiments and aspects thereof, the film includes HfO₂. In a further aspect of the forgoing embodiments and aspects thereof, the film includes HfₓZr₁₋ₓO₂ where x is a value between 0 and 1.

In a further aspect of the forgoing embodiments and aspects thereof, the film includes materials based on ZrO₂, TiO₂, HfO₂, HfₓZr₁₋ₓO₂ where x is a value between 0 and 1, or combinations thereof, with engineered impurities or dopants.

Underlying Surfaces/Substrates

As noted above, the disclosed and claimed process provides selective thermal etching of metal oxides. Such metal oxides may be disposed on, adjacent or proximate to a metal, metal nitride, or different metal oxide surface/substrate. In one embodiment, the metal, metal nitride, or different metal oxide surface/substrate includes one or more of cobalt, nickel, ruthenium, iridium, palladium, rhodium, platinum, silicon nitride, titanium nitride, and/or tantalum nitride, aluminum oxide, and/or silicon oxide. In one embodiment, the metal surface/substrate includes one or more of cobalt, nickel, ruthenium, iridium, palladium, rhodium, and/or platinum. In one embodiment, the metal nitride surface includes one or more of silicon nitride, titanium nitride, and/or tantalum nitride. In one embodiment, the different metal oxide surface/substrate includes one or more of aluminum oxide and/or silicon oxide.

The selectivity to etch the intended oxide material, and not the substrate material, as well as to minimize residues post-ALE, requires control of trace gases within the ALE chamber environment. In one embodiment, the ALE chamber environment is free of or substantially free of oxygen, ozone, or water. In one embodiment, the ALE chamber environment is free of or substantially free of oxygen. In one embodiment, the ALE chamber environment is free of or substantially free of ozone. In one embodiment, the ALE chamber environment is free of or substantially free of water.

### EXAMPLES

Reference will now be made to more specific embodiments of the present disclosure and experimental results that provide support for such embodiments. The examples are given below to more fully illustrate the disclosed subject matter and should not be construed as limiting the disclosed subject matter in any way.

It will be apparent to those skilled in the art that various modifications and variations can be made in the disclosed subject matter and specific examples provided herein without departing from the spirit or scope of the disclosed subject matter. Thus, it is intended that the disclosed subject matter, including the descriptions provided by the following examples, covers the modifications and variations of the disclosed subject matter that come within the scope of any claims and their equivalents.

### Materials and Methods

The etching processes were carried out in a warm-walled chamber system. The system includes a processing chamber, equipped with an in-situ multi-wavelength ellipsometer, a load lock and an ultrahigh vacuum analysis chamber, equipped with Auger electron spectroscope (AES). The samples are introduced into the system on a 2-inch stainless steel puck, which can be transferred between the chambers using linear transfer arms. During processing the sample was heated to a constant temperature using two PID-controlled halogen lamps. Argon (Ar, 99.999% purity) was used as a carrier and purge gas at a flow rate of 95 sccm, as set by mass-flow controllers. Thionyl chloride (SOCl₂, 99% purity) was obtained from MilliporeSigma. Boron trichloride (BCl₃, 99.9% purity), titanium tetrachloride (TiCl₄, 99% purity), and tungsten hexafluoride (WF₆, 99.99% purity) were also used. Between doses of etch process chemicals, a 15 second purge, 10 second pump, and 15 second pressurization were performed. The processing chamber was pumped out using a turbo pump (Seiko-Seiki STP-300C) and a backing pump (Alcatel 2021a) with a throttle valve located before the turbo pump used to control the operating pressure, which was set at 400 mTorr.

The TiO₂ thin films used in this study were deposited by atomic layer deposition (ALD) in the same chamber immediately before the etching process using TiCl₄ (99% purity) and deionized H₂O. The TiO₂ was deposited by ALD on chemical Si oxide at 170° C. The TiO₂ films had a starting thickness of approx. 2 nm.

The ZrO₂ thin films used in this study were deposited on Al₂O₃-coated Si substrates using an Ultratech Fiji G2 system. The deposition was carried out at 250° C. using tetrakis(dimethylamino)zirconium (TDMA-Zr) and deionized H₂O as precursors. All substrates were purged in argon and held at processing temperature for 30 minutes to allow the conditions to stabilize before etching. The ZrO₂ films had a starting thickness of approx. 3.5 nm.

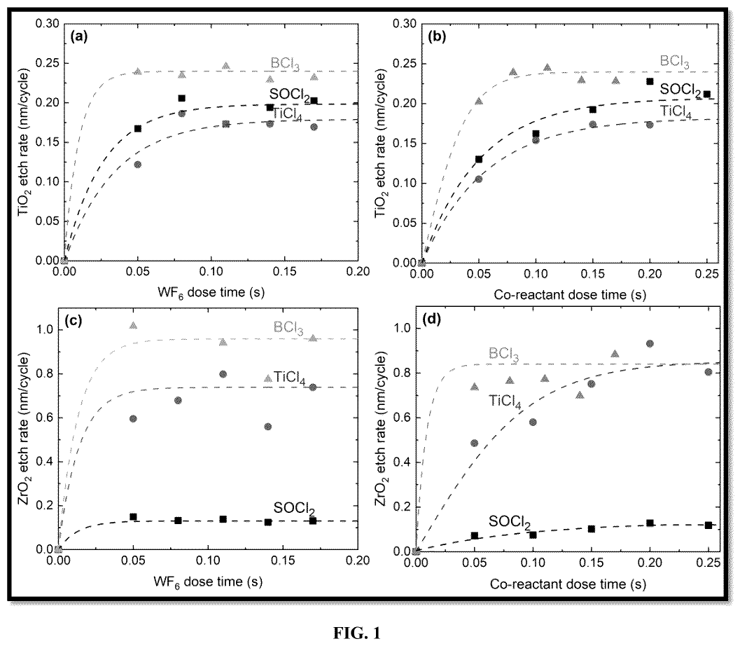

In-situ ellipsometry was used to obtain the saturation curves for TiO₂ and ZrO₂ substrates by determining the etch per cycle (EPC) dependence of the dosing time for the reactants. WF₆ dose times in the ALE cycle were fixed at 0.14 s and the dose times of chlorinating precursors were varied. Similarly, for the WF₆ saturation, the dose times of BCl₃/TiCl₄/SOCl₂ were fixed at 0.14/0.25/0.25 s, respectively, while the dose time of WF₆ was varied in independent runs. The results are plotted in FIG. 1, where the EPC is presented as an average etch rate over 10 ALE cycles carried out at 170° C. for TiO₂ and at 325° C. for ZrO₂. The data demonstrates that each of the chemistries used reached saturation thereby confirming the self-limiting nature of the process and consistent with atomic layer etching. The etch rates of TiO₂ saturated at 0.24, 0.18, and 0.20 nm/cycle for BCl₃, TiCl₄ and SOCl₂, respectively. The etch rates of ZrO₂ saturated at 0.96, 0.74 and 0.13 nm/cycle, respectively. The EPC is maximized at 0.08 s dosing times for WF₆ for all processes, while 0.08 s is required for BCl₃, and 0.2 s for both TiCl₄ and SOCl₂ to reach maximum EPC on both TiO₂ and ZrO₂.

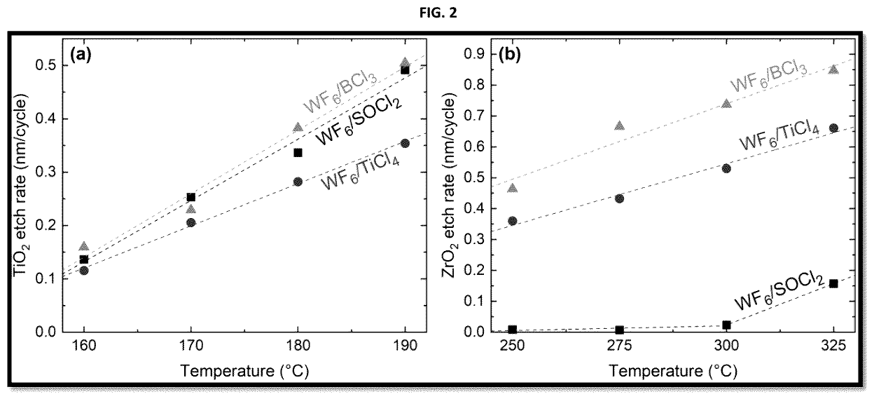

The obtained saturated dosing times were used in acquiring the EPC as a function of the sample temperature. In-situ ellipsometry measurements were performed in the temperature range of 160-190° C. for the TiO₂ and 250-325° C. for the ZrO₂ as shown in FIG. 2. The EPC is strongly dependent on the temperature and increases in linear fashion as the temperature is increased for all chemistries. The EPC of ZrO₂ using WF₆/SOCl₂ remains close to zero for temperatures ≤300° C., rising to ˜0.16 nm/cycle at 325° C. Although the reaction was predicted to occur at all temperatures by a thermodynamic model, the process is kinetically limited. The limiting step is presumed to be the fluorination of the formed Zr(SO₄)₂ by WF₆ exposure with calculated AG values of −16.4, −22.1, and −27.9 kcal at 250° C., 300° C., 350° C., respectively. In contrast, the ZrF₄ ligand exchange by SOCl₂ proceeds at calculated AG values of −906.1, −913.2, and −916.8 kcal at the same respective substrate temperatures.

### Summary of Data

It has been demonstrated that BCl₃, TiCl₄, and SOCl₂ can be used as co-etchants in a fluorination and ligand-exchange process when coupled with WF₆ to etch metal oxide materials such as TiO₂ and ZrO₂. In addition to ALE, it was shown that at temperatures above 200° C., both WF₆ and SOCl₂ led to chemical vapor etching of TiO₂, while none of the reactants individually etched ZrO₂ due to the formation of a solid layer inhibiting further reaction.

The ALE behavior was shown to be dependent on the co-etchant, temperature, and substrate material. Using in-situ ellipsometry the etch per cycle (EPC) was shown to increase linearly with the temperature for all chemistries, except for ZrO₂ etching using WF₆/SOCl₂, which was limited by the unsuccessful removal of Zr(SO₄)₂ by WF₆ exposure at temperatures ≤300° C. The etch rates of TiO₂ at 170° C. were measured as 0.24, 0.18 and 0.20 nm/cycles for WF₆ and BCl₃, TiCl₄ or SOCl₂, respectively. The respective etch rates of ZrO₂ were 0.96, 0.74 and 0.13 nm/cycle at 325° C. The higher temperature for ZrO₂ was needed due to lower volatility of the formed ZrCl₄ compared to TiCl₄. All of the etchants studied showed saturating EPC as a function of etchant dosing times, characteristic to ALE processes.

The chemical reactions and the resulting compositions were analyzed by thermodynamic modeling and in-vacuo Auger electron spectroscopy (AES) measurements. It was shown that during TiO₂ ALE that the SOCl₂ exposure leads to volatile species SO₂ and TiCl₄, in contrast to BCl₃ and TiCl₄, which result in solid B₂O₃ and TiO₂ on the surface, subsequently removed by WF₆ exposure. The ZrO₂ films were deposited on Al₂O₃ layers due to WF6 reacting with the underlying Si after the complete removal of the zirconia, leading to rapid deposition of W at temperatures above 300° C. This reaction limits the etching on Si substrate at higher temperatures. In contrast to TiO₂, all co-etchants led to formation of solid species on ZrO₂ after exposure. BCl₃ resulted in B₂O₃, TiCl₄ in TiO₂, and SOCl₂ in Zr(SO₄)₂ at 325° C. While the resulting layers are removed by subsequent WF₆ exposure, they could be undesirable reaction products when complete removal of the film is not desired. As such, co-reactant selection strongly affects the purity and surface contamination of the final sample depending on the metal oxide being etched. In addition, Zr was detected to be present on the surface after 25 ALE cycles. It is currently unclear whether further ALE cycles or higher processing temperature leads to complete removal of zirconia. The results illustrate the importance of the co-reactant design during thermal atomic layer etching processes depending on the target material to be etched, desired processing temperature range, and the substrate.

Although the disclosed and claimed subject matter has been described and illustrated with a certain degree of particularity, it is understood that the disclosure has been made only by way of example, and that numerous changes in the conditions and order of steps can be resorted to by those skilled in the art without departing from the spirit and scope of the disclosed and claimed subject matter.

1. A thermal ALE process performed in a reactor for selectively etching a metal oxide comprising:
(i) a fluorination comprising exposing a surface of the metal oxide to one or more fluorinating agent to produce a fluorinated surface;
(ii) a first purge;
(iii) a ligand-exchange comprising exposing the fluorinated surface to one or more chlorinating agent to produce a volatile chlorinated species; and
(iv) a second purge.

2. The process of claim 1, wherein the metal oxide comprises one or more of TiO₂, ZrO₂, HfO₂ and HfₓZr₁₋ₓO₂ where x is a value between 0 and 1.

3. (canceled)

4. (canceled)

5. The process of claim 1, wherein the step (i) fluorinating agent comprises one or more metal fluoride.

6. The process of claim 1, wherein the step (i) fluorinating agent comprises WF₆.

7. The process of claim 1, wherein the step (iii) chlorinating agent comprises one or more chlorine source.

8. The process of claim 1, wherein the step (iii) chlorinating agent comprises one or more of thionyl chloride (SOCl 2), titanium tetrachloride (TiCl 4), and combinations thereof.

9-11. (canceled)

12. The process of claim 1, wherein step (i) is performed at temperature between about 140° C. and about 350° C.

13-42. (canceled)

43. The process of claim 1, wherein step (iii) is performed at temperature between about 140° C. and about 350° C.

44-76. (canceled)

77. The process of claim 1, wherein one cycle of the process is determined by the formula (step i)ₙ+(step iii)ₘ, wherein n and m are each independently=1-20.

78-103. (canceled)

104. The process of claim 77, wherein the process comprises about 5 to about 5000 cycles.

105-124. (canceled)

125. The process of claim 1, wherein each iteration of step (i) takes between about seconds and about 60 seconds.

126. The process of claim 1, wherein each iteration of step (iii) takes between about seconds and about 60 seconds.

127-132. (canceled)

133. The process of claim 1, wherein a total pressure in the chamber during fluorinating agent delivery is from about 0.1 Torr to about 1.0 Torr.

134. The process of claim 1, wherein a total pressure in the chamber during chlorinating agent delivery is from about 0.1 Torr to about 1.0 Torr.

135-137. (canceled)

138. A film modified or etched by the process of claim 1, wherein the film comprises trenches, vias or other topographical features with an aspect ratio of about 0 to about 60.

139. A film modified or etched by the process of claim 1, wherein the film comprises one or more of titanium, hafnium and zirconium.

140. (canceled)

141. (canceled)

142. A film modified or etched by the process of claim 1, wherein the film comprises TiO₂.

143. A film modified or etched by the process of claim 1, wherein the film comprises ZrO₂.

144. (canceled)

145. (canceled)

146. A film modified or etched by the process of claim 1, wherein the film comprises HfO₂.

147. (canceled)

148. A film modified or etched by the process of claim 1, wherein the film comprises HfₓZr₁₋ₓO₂ where x is a value between 0 and 1.
